(19) United States
(12) Patent Application Publication
(10) Pub. No.: US 2021/0305051 A1
(43) Pub. Date: Sep. 30, 2021

(54) Metal Wiring Method for Reducing Gate Resistance of a Narrow Control Gate Structure

(71) Applicant: University of Electronic Science and Technology of China, Chengdu (CN)

(72) Inventors: Ming QIAO, Chengdu (CN); Shida DONG, Chengdu (CN); Zhengkang WANG, Chengdu (CN); Dong FANG, Chengdu (CN); Zhuo WANG, Chengdu (CN); Bo ZHANG, Chengdu (CN)

(73) Assignee: University of Electronic Science and Technology of China, Chengdu (CN)

(21) Appl. No.: 17/004,031

(22) Filed: Aug. 27, 2020

(30) Foreign Application Priority Data
Mar. 28, 2020 (CN) 202010232579.X

(51) Int. Cl. H01L 21/28; H01L 29/78; H01L 29/10; H01L 29/40; H01L 29/417; H01L 29/423; H01L 21/765; H01L 29/66

(52) U.S. Cl. CPC H01L 21/28114; H01L 29/7813; H01L 29/1095; H01L 29/407; H01L 29/66734; H01L 29/42376; H01L 21/765; H01L 29/66727; H01L 29/41741

(57) ABSTRACT

A metal wiring method for reducing gate resistance of a narrow control gate structure, wherein the gate structure is etched with first gate electrodes and second gate electrodes at regular intervals and kept with complete gate electrodes at regular intervals, thereby constituting a structure in which the first and second gate electrodes and the complete gate electrodes are spaced apart. A first contact hole is etched on the complete gate electrode to draw out metal as a first metal layer. A second contact hole is etched on a source region and a split gate to draw out metal as a second metal layer. These two metal layers are separated by a dielectric layer. A multi-point contact of the first layer of metal with the gate electrode in a Y direction reduces the gate resistance caused by an excessively long path in the Y direction of a control gate electrode.

### CROSS-REFERENCE TO THE RELATED APPLICATION

This application is based upon and claims priority to Chinese Patent Application No. 202010232579.X, filed on Mar. 28, 2020, the entire contents of which are incorporated herein by reference.

### TECHNICAL FIELD

The present invention belongs to the field of semiconductor technology, and in particular to a metal wiring method for reducing gate resistance of a narrow control gate structure.

### BACKGROUND

A power management system requires a power semiconductor device to have low on-resistance and parasitic capacitance to reduce device conduction losses and switching losses. Power VDMOS is widely used in power management systems due to its features such as low gate drive power consumption, fast switching speed and easy parallel connection. Chinese Patent Application No. 201910191166.9 invented by Qiao Ming, Wang Zhengkang, Zhang Bo et al. and U.S. patent application Ser. No. 16/536,333 entitled “Split-Gate Enhanced Power MOS Device” present a trench metal oxide semiconductor field effect transistor having a narrow gate structure. However, the gate structure is too narrow and an electrode is drawn out at an edge, resulting in an excessively long path, which brings about a problem of excessively large gate resistance. Excessively large gate resistance causes excessively large losses.

Therefore, in view of the above problems, it is necessary to reduce the problem of excessively large gate resistance brought about by the narrow gate structure, and the embodiments of the present invention are invented under such a background.

### SUMMARY

The present invention presents a metal wiring method for reducing gate resistance of a narrow control gate structure, which optimizes metal wiring for the problem of excessively large gate resistance brought about by the structure proposed by Chinese Patent Application No. 201910191166.9 invented by Qiao Ming, Wang Zhengkang, Zhang Bo et at and U.S. patent application Ser. No. 16/536,333 entitled “Split-Gate Enhanced Power MOS Device”. In the traditional wiring method as shown in FIG. 3, gate electrodes are drawn out at the edges. However, the narrow gate structure improved by the above patents narrows the current path, thereby greatly increasing gate resistance and switching losses.

To achieve the above-mentioned purpose of the invention, technical solutions of the present invention is as follows:

A metal wiring method for reducing gate resistance of a narrow control gate structure, wherein the gate structure is etched with first gate electrodes 131 and second gate electrodes 132 at regular intervals and kept with complete gate electrodes at regular intervals, thereby constituting a structure in which the first and second gate electrodes and the complete gate electrodes are spaced apart; a contact hole is etched on the complete gate electrode to draw out metal as a first layer of metal 15; contact holes are etched on a source region and a split gate to draw out metal as a second layer of metal 19; these two layers of metal are separated by a dielectric layer 11; a multi-point contact of the first layer of metal with the gate electrode in a Y direction solves a problem of gate resistance increase brought about by an excessively long path in the Y direction of a control gate electrode, meanwhile, magnitude of the gate resistance is control led by controlling the intervals of the adjacent complete gate electrodes in the Y direction, so that a metal oxide semiconductor field effect transistor having a narrow gate structure with low gate resistance is obtained by using a plurality of layers of metal.

As a preferred embodiment, a first conductivity type epitaxial layer 26 is provided on an upper surface of a first conductivity type substrate 29, and a control gate trench is provided in the first conductivity type epitaxial layer 26; a control gate electrode 13 and a split gate electrode 22 are contained in the control gate trench; the control gate electrode 13 includes a first gate electrode 131 and a second gate electrode 132; the first gate electrode 131 and the second gate electrode 132 are located on an upper half portion of the control gate trench; the first gate electrode 131 and the second gate electrode 132 are connected at a certain distance in the Y direction, and non-connected portion of the first gate electrode and the second gate electrode is separated by the dielectric layer 11; the first gate electrode 131 and the second gate electrode 132 are located above the split gate electrode 22, and are separated from the split gate electrode 22 by the dielectric layer 11; the split gate electrode 22 is located on a lower half portion of the control gate trench, and is separated from the first conductivity type epitaxial layer 26 by the dielectric layer 11; between adjacent control gate trenches, a second conductivity type well region 25 is provided above the first conductivity type epitaxial layer 26; a second conductivity type heavily doped region 251 is provided in the second conductivity type well region 25, and a first conductivity type heavily doped source region 18 is provided above the second conductivity type well region 25; a contact hole is etched on a junction of the first gate electrode 131 and the second gate electrode 132 to draw out metal as the first layer of metal 15; the first conductivity type heavily doped source region 18, contact holes are etched on the second conductivity type heavily doped region 251 and the split gate electrode 22 to draw out metal as the second layer of metal 19; the first layer of metal 15 and the second layer of metal 19 are separated by the dielectric layer 11.

As a preferred embodiment, the method includes the following steps:

1) Forming a series of the trenches on the epitaxial layer;

2) Forming the split gate electrode on the lower half portion of the control gate trench in an active region;

3) Forming a layer of the dielectric layer in the trench in the active region and on the upper portion of the split gate;

4) Forming a gate dielectric covering a sidewall on the upper half portion of the control gate trench in the active region; subsequently depositing a gate electrode in the active region;

5) Separating a central portion of the control gate by etching at a certain distance in the Y direction, thereby forming the first gate electrode and the second gate electrode, which are connected and covering the upper half portion of the sidewall of the control gate trench;

6) Forming a second conductivity type body region on the upper surface of the epitaxial layer, and forming a first conductivity type source electrode in the second conductivity type body region;

7) Etching a gate contact hole in the Y direction at the junction of the first gate electrode and the second gate electrode to draw out gate electrode metal as the first layer of metal;

8) Depositing the dielectric layer;

9) Etching a source contact hole in the source region and a split gate draw-out region to draw out source metal as the second layer of metal.

As a preferred embodiment, the dielectric layer separating the first layer of metal and the second layer of metal is made of a low-k material.

As a preferred embodiment, the distance between adjacent gate contact holes 14 in the Y direction is arbitrarily adjustable to meet different requirements of the gate resistance.

As a preferred embodiment, the distance between adjacent complete gate electrode portions in the Y direction is arbitrarily adjustable to meet different requirements of the gate resistance.

As a preferred embodiment, all of the first gate electrodes and the second gate electrodes are separated by etching in the Y direction, and spaced contact holes are provided at a contact portion of the gate electrodes.

As a preferred embodiment, the wiring method is also applicable to structures such as a non-narrow gate structure and a non-split gate structure.

The beneficial effects of the present invention are: the structure proposed by Chinese Patent Application No. 201910191166.9 invented by Qiao Ming, Wang Zhengkang, Zhang Bo et al. and U.S. patent application Ser. No. 16/536,333 entitled “Split-Gate Enhanced Power MOS Device” is improved by using a plurality of layers of metal; the problem of gate resistance increase brought about by the excessively long path in the Y direction of the control gate electrode is effectively reduced by the multi-point contact of the first layer of metal with the gate electrode in the Y direction, meanwhile, magnitude of the gate resistance can be controlled by controlling the distance and density of contact points of the metal and the control gate in the Y direction, thereby greatly increasing design flexibility. Therefore, a metal oxide semiconductor field effect transistor having a narrow gate structure with low gate resistance can be obtained by using a plurality of layers of metal, thereby enabling the device of the present invention to have both properties of low gate capacitance and low gate resistance.

### BRIEF DESCRIPTION OF THE DRAWINGS

FIG. 1 is a metal wiring diagram of a traditional split gate structure

FIG. 2 is a cross-sectional view at AA′ in FIG. 1.

FIG. 3 is a top view of a metal wiring method of a trench metal oxide semiconductor field effect transistor having a narrow gate structure according to Embodiment 1 of the present invention.

FIG. 4A is a cross-sectional view taken at the position AA′ in FIG. 3.

FIG. 4B is a cross-sectional view taken at the position BB′ in FIG. 3.

FIG. 5 is a metal wiring diagram and a gate structure based on the present invention, as provided by Embodiment 2 of the present invention.

FIG. 6A is a cross-sectional view taken at the position AA′ in FIG. 5.

FIG. 6B is a cross-sectional view taken at the position BB′ in FIG. 5.

FIG. 7 is a metal wiring diagram and a gate structure based on the present invention, as provided by Embodiment 3 of the present invention.

FIG. 8 is a cross-sectional view taken at the position AA′ in FIG. 7.

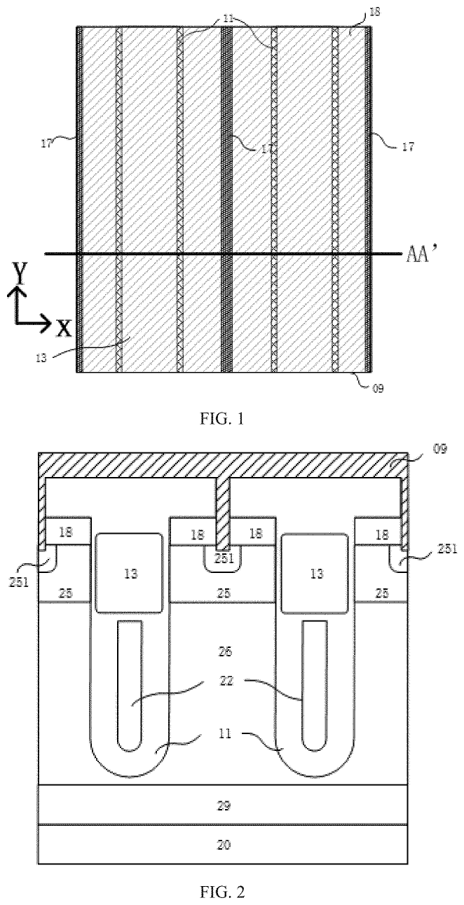

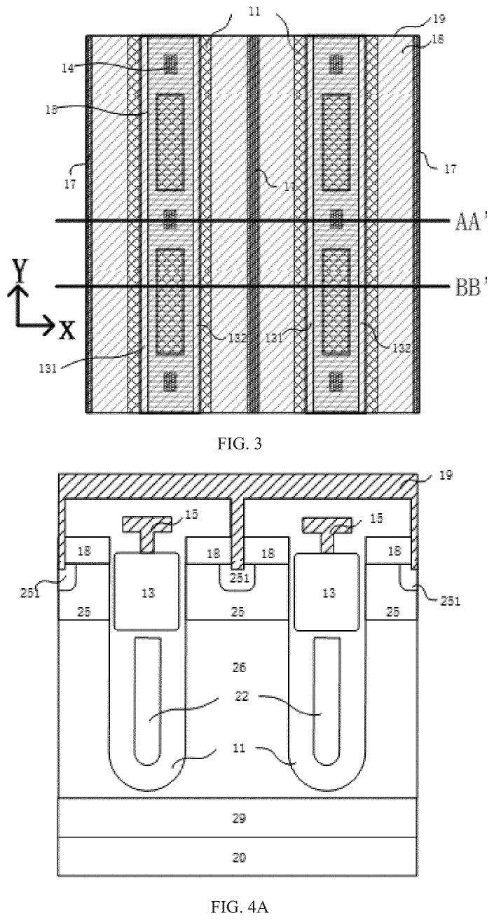

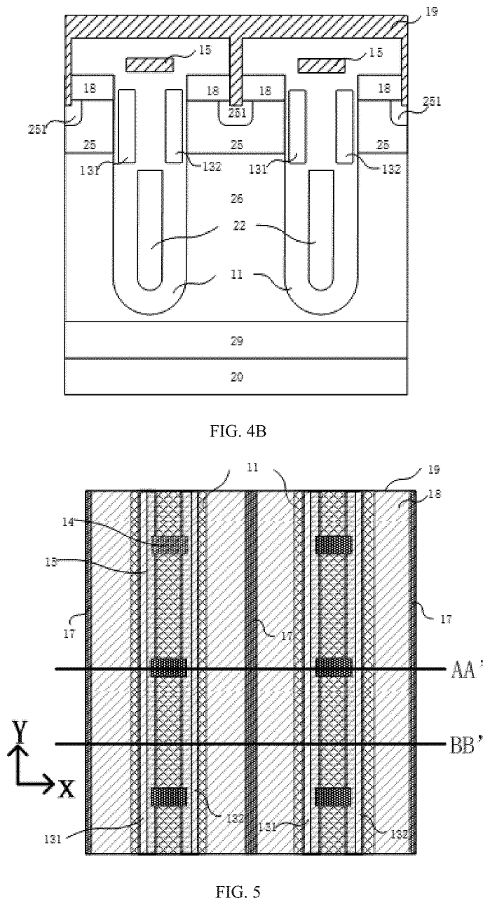

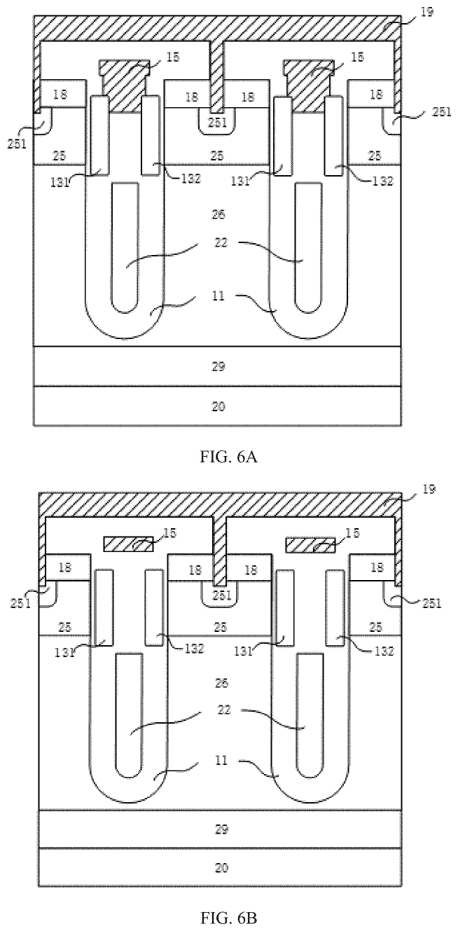

Wherein, 11-dielectric layer, 13-control gate electrode, 131-first gate electrode, 132-second gate electrode, 14-gate contact hole, 15-first layer of metal, 17-source contact hole, 18-first conductivity type heavily doped region, 19-second layer of metal, 20-bottom electrode, 22-split gate electrode, 25-second conductivity type well region, 251-second conductivity type heavily doped region, 26-first conductivity type epitaxial layer, 29-first conductivity type substrate.

### DETAILED DESCRIPTION

### Embodiment 1

As shown in FIG. 3, this embodiment provides a metal wiring method for reducing gate resistance of a narrow control gate structure, wherein the gate structure is etched with first gate electrodes 131 and second gate electrodes 132 at regular intervals and kept with complete control gate electrodes at regular intervals, thereby constituting a structure in which the first and second gate electrodes and the complete gate electrodes are spaced apart; a contact hole is etched on the complete gate electrode to draw out metal as a first layer of metal 15; contact holes are etched on a source region and a split gate to draw out metal as a second layer of metal 19; these two layers of metal are separated by a dielectric layer 11; a multi-point contact of the first layer of metal with the gate electrode in a Y direction solves a problem of gate resistance increase brought about by an excessively long path in the Y direction of a control gate electrode, meanwhile, magnitude of the gate resistance is controlled by controlling the intervals of the complete gate electrodes in the Y direction, so that a metal oxide semiconductor field effect transistor having a narrow gate structure with low gate resistance is obtained by using a plurality of layers of metal.

A first conductivity type epitaxial layer 26 is provided on an upper surface of a first conductivity type substrate 29, and a control gate trench is provided in the first conductivity type epitaxial layer 26; a control gate electrode 13 and a split gate electrode 22 are contained in the control gate trench; the control gate electrode 13 includes a first gate electrode 131 and a second gate electrode 132; the first gate electrode 131 and the second gate electrode 132 are located on an upper half portion of the control gate trench; the first gate electrode 131 and the second gate electrode 132 are connected at a certain distance in the Y direction, and non-connected portion of the first gate electrode and the second gate electrode is separated by the dielectric layer 11; the first gate electrode 131 and the second gate electrode 132 are located above the split gate electrode 22, and are separated from the split gate electrode 22 by the dielectric layer 11; the split gate electrode 22 is located on a lower half portion of the control gate trench, and is separated from the first conductivity type epitaxial layer 26 by the dielectric layer 11; between adjacent control gate trenches, a second conductivity type well region 25 is provided above the first conductivity type epitaxial layer 26; a second conductivity type heavily doped region 251 is provided in the second conductivity type well region 25, and a first conductivity type heavily doped source region 18 is provided above the second conductivity type well region 25; a contact hole is etched on a junction of the first gate electrode 131 and the second gate electrode 132 to draw out metal as the first layer of metal 15; the first conductivity type heavily doped source region 18, contact holes are etched on the second conductivity type heavily doped region 251 and the split gate electrode 22 to draw out metal as the second layer of metal 19; the first layer of metal 15 and the second layer of metal 19 are separated by the dielectric layer 11.

The method includes the following steps:

1) Forming a series of the trenches on the epitaxial layer;

2) Forming the split gate electrode on the lower half portion of the control gate trench in an active region;

3) Forming a layer of the dielectric layer in the trench in the active region and on the upper portion of the split gate;

4) Forming a gate dielectric covering a sidewall on the upper half portion of the control gate trench in the active region; subsequently depositing a gate electrode in the active region;

5) Separating a central portion of the control gate by etching at a certain distance in the Y direction, thereby forming the first gate electrode and the second gate electrode, which are connected and covering the upper half portion of the sidewall of the control gate trench;

6) Forming a second conductivity type body region on the upper surface of the epitaxial layer, and forming a first conductivity type source electrode in the second conductivity type body region;

7) Etching a gate contact hole in the Y direction at the junction of the first gate electrode and the second gate electrode to draw out gate electrode metal as the first layer of metal;

8) Etching a source contact hole in the source region and a split gate draw-out region to draw out source metal as the second layer of metal.

Preferably, the dielectric layer separating the first layer of metal and the second layer of metal is made of a low-k material.

Preferably, the distance between adjacent gate contact holes 14 in the Y direction is arbitrarily adjustable to meet different requirements of the gate resistance.

Preferably, the distance between adjacent complete gate electrode portions in the Y direction is arbitrarily adjustable to meet different requirements of the gate resistance.

Preferably, all of the first gate electrodes and the second gate electrodes are separated by etching in the Y direction, and spaced contact holes are provided at a contact portion of the gate electrodes.

### Embodiment 2

As shown in FIG. 5, the differences between this embodiment and Embodiment 1 are: all of the first gate electrodes 131 and the second gate electrodes 132 are separated, and are connected by the gate contact holes 14 rather than the gates themselves; in addition, the width of the gate contact hole 14 is larger than that of the dielectric layer 11 between the first gate electrode 131 and the second gate electrode 132.

### Embodiment 3

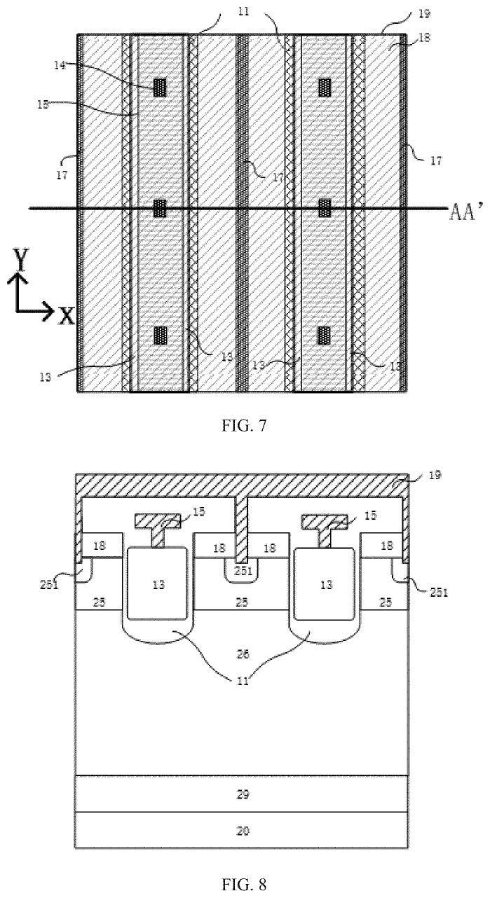

As shown in FIG. 7, the differences between this embodiment and Embodiment 1 are: this embodiment illustrates a traditional structure having no narrow gate or split gate, namely the control gate 13 is not separated by etching in the Y direction; and no split gate 22 structure is provided in the trench. This embodiment is intended to illustrate that the present invention is also applicable to a traditional structure having no narrow gate or split gate.

FIG. 8 is a cross-sectional view taken at AA′ in FIG. 7 in which no split gate structure is provided and the control gate is a complete structure.

The embodiments of the present invention have been described in detail above with reference to the accompanying drawings, but the present invention is not limited to the above-mentioned specific embodiments. The above-mentioned specific embodiments are only illustrative and not restrictive. Under the enlightenment of the present invention, many variations can be made by those of ordinary skill in the art without departing from the purpose of the present invention and the protection scope of the claims, all of which belong to the protection of the present invention.

What is claimed is:

1. A metal wiring method for reducing a gate resistance of a narrow control gate structure, wherein the narrow control gate structure is etched with first gate electrodes and second gate electrodes at regular intervals and kept with complete gate electrodes at regular intervals to constitute a structure, wherein the first gate electrodes, second gate electrodes and the complete gate electrodes are spaced apart in the structure;
a first contact hole of contact holes is etched on a complete gate electrode of the complete gate electrodes to draw out a first metal as a first metal layer;
a second contact hole of the contact holes is etched on a source region and a split gate to draw out a second metal as a second metal layer;
the first metal layer and the second metal layer are separated by a dielectric layer;
a multi-point contact of the first metal layer with a gate electrode in a Y direction reduces the gate resistance caused by a long path in the Y direction of a control gate electrode; and
a magnitude of the gate resistance is controlled by controlling intervals of the complete gate electrodes in the Y direction, to obtain a metal oxide semiconductor field effect transistor having the narrow control gate structure with the gate resistance by using the first metal layer and the second metal layer.

2. The metal wiring method according to claim 1, wherein:
a first conductivity type epitaxial layer is provided on an upper surface of a first conductivity type substrate, and a control gate trench is provided in the first conductivity type epitaxial layer;
the control gate electrode and a split gate electrode are contained in the control gate trench;
the control gate electrode comprises a first gate electrode of the first gate electrodes and a second gate electrode of the second gate electrodes;
the first gate electrode and the second gate electrode are located on an upper half portion of the control gate trench;
the first gate electrode and the second gate electrode are connected at a distance in the Y direction, and a non-connected portion of the first gate electrode and the second gate electrode is separated by the dielectric layer;
the first gate electrode and the second gate electrode are located above the split gate electrode, and are separated from the split gate electrode by the dielectric layer;
the split gate electrode is located on a lower half portion of the control gate trench, and is separated from the first conductivity type epitaxial layer by the dielectric layer;
between adjacent control gate trenches, a second conductivity type well region is provided above the first conductivity type epitaxial layer;
a second conductivity type heavily doped region is provided in the second conductivity type well region, and a first conductivity type heavily doped source region is provided above the second conductivity type well region;
the first contact hole of the contact holes is etched on a junction of the first gate electrode and the second gate electrode to draw out the first metal as the first metal layer;
the second contact hole of contact holes is etched on the first conductivity type heavily doped source region, the second conductivity type heavily doped region and the split gate electrode to draw out the second metal as the second metal layer; and
the first metal layer and the second metal layer are separated by the dielectric layer.

3. The metal wiring method according to claim 2, comprising the following steps:
1) forming a plurality of trenches on an epitaxial layer;
2) forming the split gate electrode on the lower half portion of the control gate trench in an active region;
3) forming the dielectric layer in the control gate trench in the active region and on an upper portion of the split gate;
4) forming a gate dielectric covering a sidewall on the upper half portion of the control gate trench in the active region; subsequently depositing the gate electrode in the active region;
5) separating a central portion of the narrow control gate structure by etching at a distance in the Y direction to form the first gate electrode and the second gate electrode, wherein the first gate electrode and the second gate electrode are connected and cover an upper half portion of the sidewall of the control gate trench;
6) forming a second conductivity type body region on an upper surface of the epitaxial layer, and forming a first conductivity type source electrode in the second conductivity type body region;
7) etching a gate contact hole in the Y direction at the junction of the first gate electrode of the first gate electrodes and the second gate electrode of the second gate electrodes to draw out a gate electrode metal as the first metal layer;
8) depositing the dielectric layer;
9) etching a source contact hole in the source region and the split gate draw-out region to draw out a source metal as the second metal layer.

4. The metal wiring method according to claim 1, wherein the dielectric layer separating the first metal layer and the second metal layer of is made of a low-k material.

5. The metal wiring method according to claim 1, wherein a distance between adjacent gate contact holes in the Y direction is adjustable to meet different requirements of the gate resistance.

6. The metal wiring method according to claim 1, wherein a distance between adjacent complete gate electrode portions in the Y direction is adjustable to meet different requirements of the gate resistance.

7. The metal wiring method according to claim 1, wherein all of the first gate electrodes and the second gate electrodes are separated by etching in the Y direction, and spaced contact holes are provided at a contact portion of the first gate electrodes and the second gate electrodes.

8. The metal wiring method according to claim 1, wherein the metal wiring method is applied to a traditional structure having no narrow gate or the split gate.
